(19) United States
(12) Patent Application Publication
(10) Pub. No.: US 2013/0213467 A1
(43) Pub. Date: Aug. 22, 2013

(54) PRODUCTION OF MICROHOLES

(71) Applicants: Kurt Nattermann, Ockenheim (DE); Ulrich Peuchert, Bodenheim (DE); Wolfgang Moehl, Worms (DE)

(72) Inventors: Kurt Nattermann, Ockenheim (DE); Ulrich Peuchert, Bodenheim (DE); Wolfgang Moehl, Worms (DE)

(73) Assignee: Schott AG, Mainz (DE)

(21) Appl. No.: 13/807,407

(22) PCT Filed: Jul. 4, 2011
(86) PCT No.: PCT/EP2011/003302

§ 371 Date: Feb. 22, 2013

(30) Foreign Application Priority Data
Jul. 2, 2010 (DE) 10 2010 025 968.3

(51) Int. Cl. H01L 31/18; H01L 21/3065; H01L 31/0248; B26F 1/28

(52) U.S. Cl. CPC H01L 31/18; B26F 1/28; H01L 21/3065; H01L 31/0248
USPC 136/256; 427/532; 216/13; 118/620; 438/694; 428/131

(57) ABSTRACT

A method and apparatus for producing a multiplicity of holes in thin sheet-like workpieces of dielectric material or semiconductors is provided. The perforation points are marked by HF coupling points and caused to soften using HF energy in order to obtain dielectric breakdowns. The breakdowns are then widened into holes.

### FIELD OF THE INVENTION

The invention relates to methods for producing a multiplicity of holes in thin sheet-like workpieces of dielectric material or semiconductors, and further relates to an apparatus for carrying out the method and to articles produced by such method.

### BACKGROUND OF THE INVENTION

The perforation of plastic films by electrically generated sparks is known from U.S. Pat. No. 4,777,338. A plurality of electrode-counter electrode pairs is provided, between which the plastic film is guided and across which high-voltage energy is discharged. The film is moved through a water bath, and the temperature of the water bath is utilized to control the size of the perforations.

Another method for producing pores in plastic films is known from U.S. Pat. No. 6,348,675 B1. Pulse sequences are generated between electrode pairs, with the plastic film interposed therebetween, the first pulse serving to heat the plastic film at the perforation point and the further pulses serving to form the perforation and to shape it.

From U.S. Pat. No. 4,390,774, the treatment of non-conductive workpieces by electrical means is known in the sense of cutting the workpiece or welding the workpiece. A laser beam is directed onto the workpiece which is moved during the exposure, and a high-voltage is applied to the heated zone using two electrodes to form an arc which serves to process the workpiece. During cutting of the workpiece it burns in controlled manner, or electrical conductivity thereof increases with temperature, similarly to the cutting of glass. When workpieces are to be welded, streams of reactive or inert gas are additionally directed to the heated zone to react with either the workpiece or the electrode or a fluxing agent. In this way, glass, paper, cloth, cardboard, leather, plastics, ceramics, and semiconductors can be cut, or glass and plastics can be welded, rubber can be vulcanized, and synthetic resins can be cured thermally. However, the equipment is too clunky by its nature as to permit thin holes to be formed in the workpiece.

From WO 2005/097439 A2 a method is known for forming a structure, preferably a hole or cavity or channel, in a region of an electrically insulating substrate, in which energy, preferably in form of heat, also by a laser beam, is supplied to the substrate or region, and a voltage is applied to the region to produce a dielectric breakdown there. The process is controlled using a feedback mechanism. It is possible to produce thin individual holes one after the other, however it is not possible to employ a plurality of electrode pairs simultaneously. This is because parallel high voltage electrodes mutually influence each other and a single breakdown attracts the entire current.

From WO 2009/059786 A1 a method is known for forming a structure, in particular a hole or cavity or channel or recess, in a region of an electrically insulating substrate, in which stored electrical energy is discharged across the region and additional energy, preferably heat, is supplied to the substrate or the region to increase electrical conductivity of the substrate or region and thereby initiate a current flow, the energy of which is dissipated in the substrate, i.e. converted into heat, wherein the rate of dissipation of the electrical energy is controlled by a current and power modulating element. An apparatus for simultaneously producing a plurality of holes is not disclosed.

WO 2009/074338 A1 discloses a method for introducing a change of dielectric and/or optical properties in a first region of an electrically insulating or electrically semi-conducting substrate, wherein the substrate whose optical or dielectric properties are irreversibly altered due to a temporary increase in substrate temperature, optionally has an electrically conductive or semi-conductive or insulating layer, wherein electrical energy is supplied to the first region from a voltage supply to significantly heat or melt parts or all of the first region without causing an ejection of material from the first region, and wherein furthermore, optionally, additional energy is supplied to generate localized heat and to define the location of the first region. The dissipation of electrical energy manifests itself in form of a current flow within the substrate. The dissipation of the electrical energy is controlled by a current and power modulating element. Alterations in substrate surfaces produced by the method also include holes produced in borosilicate glass or silicon substrates which had been provided with an insulating layer of paraffin or a hot melt adhesive. Also, holes are produced in silicon, in zirconia, in sapphire, in indium phosphide, or gallium arsenide. Partially, the discharge process was initiated by laser beam irradiation at a wavelength of 10.6 μm (CO₂ laser). Grids of holes are also disclosed, but with relatively large spacings of the holes. An apparatus for simultaneously producing a plurality of holes is not disclosed.

DE 2830326 A1 discloses an arrangement for effecting superfine perforation of film-like sheeting using high voltage pulses. Pairs of needles are used as electrode and counter electrode, which are arranged in staggered rows and controlled successively in groups, while the sheetings are passed between the multi-row needle arrays by a transport roller. For each of the opposing pairs of needles in the needle arrays, an excitation circuit is provided.

Therefore, it is clear from prior art how to perforate foils and thin sheets of dielectric materials using a high voltage electric field of appropriate frequency or pulse shape. Local heating of the material reduces the dielectric strength at the points to be perforated, so that the applied field strength is sufficient to cause an electric current to flow across the material. If the material exhibits a sufficiently large increase in electrical conductivity with temperature, as is the case with glasses, glass-ceramics, and semi-conductors (also with many plastics), the result is an “electro-thermal self-focusing” of the perforation channel in the material. The perforation material is getting hotter and hotter, current density increases until the material is evaporated and the perforation is “blown open”. However, since the perforation is based on a dielectric breakdown, it is difficult to exactly match the desired location of the breakdown. As is known, flashes follow a very irregular course.

CPU chips have several hundred contact points distributed over a small area on the bottom surface thereof. In order to produce supply lines to the contact points, thin sheets (<1 mm) are used, i.e. fiberglass mats coated with epoxy material referred to as “interposers”, through which the supply lines extend. To this end, several hundred holes are placed in the interposer and filled with conductive material. Typical hole sizes range from 250 to 450 μm per hole. There should not be any alterations in length between CPU chip and interposer. Therefore, the interposers should exhibit a thermal expansion behavior similar to that of the semiconductor material of the chip, which, however, is not the case with previously used interposers.

In solar technology, for manufacturing solar cells a multiplicity of holes (depending on the technology used, from 10 to 100, or in the order of several 10,000 holes) are drilled into silicon wafers, in order to extend, in subsequent process steps, thin fingers from rear contacts to the front surface of the corresponding solar cell. The holes are produced using masking and etching techniques, which are not particularly well suited for producing cylindrical holes with smooth (fire-polished) hole walls and high aspect ratios (sheet thickness to hole diameter). It is also known to produce holes in solar panels by laser drilling, but this is extremely expensive.

What is also lacking in the prior art is the manufacturing of a multiplicity of thin holes adjacent to one another on an industrial scale, with hole-to-hole spacings ranging from 120 μm to 400 μm, and using the electro-thermal perforation process.

### GENERAL DESCRIPTION OF THE INVENTION

An object of the invention is to provide a method and an apparatus for producing a multiplicity of holes in thin sheet-like workpieces of dielectric material or semiconductors, if the following requirements have to be met:

The holes have to be positioned precisely (±20 μm).

It has to be possible to accommodate many small holes (from 10 to several 10,000) per workpiece with hole-to-hole tight tolerances.

The hole-to-hole spacing may be small (30 μm to 1000 μm). The holes should be producible on an industrial scale.

The method according to the invention should in particular be suitable to produce “glass interposers” with the following properties:
The glass interposers should have a large number of holes, for example between about 1000 and 5000.
The hole diameters should range from 20 μm to 450 μm, a range from 50 μm to 120 μm being preferred, with aspect ratios (glass thickness to hole diameter) from 1 to 10.
A center-to-center distance of the holes in a range from 120 μm to 400 μm has to be possible.
The hole should be shaped to have rounded edges at the inlet and outlet of the hole and to be cylindrical inside the sheet.
Optionally, a bead around the edge of the hole may be permitted with a bead height of not more than 5 μm.
The walls of the hole should be smooth (fire-polished).

Furthermore, the method should permit to produce solar cells which typically comprise silicon wafers of a sheet thickness from 0.12 to 0.3 mm and with an edge length of the sheet from 125 to 250 mm, and which are to be provided with a large number of holes (from 10 to several 10,000). The holes should have diameters ranging from 50 to 200 μm. The hole walls should be smooth (fire-polished).

The method according to the invention may be performed in two steps. First, dielectric breakdowns may be produced at the intended perforation points, and in the second step these dielectric breakdowns may be widened.

To precisely mark the locations of dielectric breakdowns, coupling material is printed to the intended perforation points of the respective workpiece, in form of dots. The coupling material is activated, e.g. by being heated. Or, the printed workpiece is introduced between plate-shaped HF electrodes, and the output of HF energy causes stronger heating of the workpiece between the dots of coupling material until the workpiece material softens there, whereby the resistance to electric breakdown is reduced. When now a high voltage is applied across the electrodes, dielectric breakdowns are caused at the coupling points.

In case the dielectric material consists of glass or glass-like material, a glass paste may be used as a coupling material, which exhibits high dielectric losses when subjected to HF energy. In case of glass, glass-like material, or semiconductor material, a paste with conductive components is likewise conceivable as a coupling material. Such paste may contain metallic particles, or metallic particles may be released by the action of thermal and/or chemical processes. Such conductive components may form respective micro-antennas for supplied high-frequency energy at the intended perforation points, which is useful for a rapid development of dielectric breakdowns.

In further processing, the produced dielectric breakdowns are enlarged. For this purpose, the method of electro-thermal self-focusing of the breakdown channel may be employed, i.e. completion of the respective hole to be formed may be achieved by continuing to apply a high voltage of appropriate frequency or pulse shape.

However, the holes may likewise be widened by chemical means. In case of workpieces of glass or glass-like materials, a supply of halogen-like reactive gases causes a depletion of silicon in the region of the dielectric breakdowns, which shifts the softening point of the glass towards lower temperatures, thereby accelerating the erosion of material. The holes may also be widened using plasma chemistry, i.e. by deep reactive ion etching. Alternating cycles of etching and passivation may be employed. In case of glass workpieces, etching may be accomplished using CF₄ gas or SF₆ gas, and passivation may be accomplished using C₄F₈ gas.

Widening of the holes may be accomplished in a combined apparatus together with the generation of the dielectric breakdowns, but it is also possible to use separate apparatus for producing the dielectric breakdowns and for widening. In any case it is advantageous for the reactive gases to be directed onto the points of holes being formed in form of jet streams. Once the holes have been formed, purge gases are used to remove the eroded hole material.

The apparatus for carrying out the method comprises two mutually parallel plates confining the processing space for the workpiece. These parallel plates may simultaneously form an HF electrode and an HF counter electrode, respectively. A workpiece holder supports the workpiece at the correct position within the processing space. An HF generator is provided to supply high frequency energy to the electrode-counter electrode pair and to heat the HF coupling material provided at the intended perforation points. At these heated points the dielectric strength of the material is reduced, so that when a high voltage is applied to the electrode-counter electrode pair dielectric breakdowns are triggered at the intended perforation points.

If chemical widening of the dielectric breakdowns is to be employed, the apparatus comprises nozzle bores aligned towards the intended perforation points of the workpiece, which nozzle bores are connected to gas supply lines. Furthermore, gas suction means are connected to the processing space to discharge excessive gas and eroded perforation material.

### BRIEF DESCRIPTION OF THE DRAWING

Exemplary embodiments of the invention will now be described with reference to the drawings, wherein:

FIG. 1 shows an apparatus for producing dielectric breakdowns in thin sheet-like workpieces; and

FIG. 2 shows an apparatus for widening dielectric breakdowns.

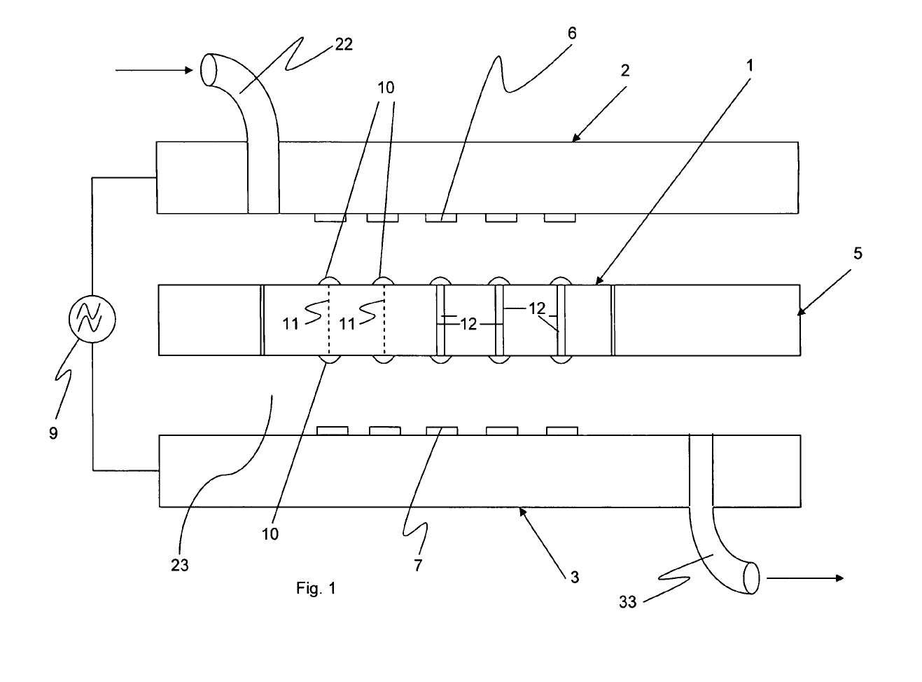

FIG. 1 schematically illustrates an apparatus for producing dielectric breakdowns 11 in a thin (<1 mm) sheet-like workpiece 1 of dielectric material or semiconductors. The workpiece 1 has been printed with coupling material 10 in form of dots at the intended perforation points, which may be accomplished in high-precision manner according to the local coordinates of the holes to be formed using printing processes.

The apparatus comprises two mutually parallel electrodes 2, 3, which may be energized by an HF generator 9. The intermediate space between the electrodes forms a processing space 23 in which the workpiece 1 is supported by a workpiece holder 5. Electrodes 2, 3 may have plate-shaped or annular electrode projections 6, 7, which (in contrast to the drawing) are closely adjacent to or even slightly engage the coupling points 10. For this purpose, workpiece holder 5 permits to precisely displace the workpiece 1 based on coordinates, so that the electrode projections 6, 7 are aligned with HF coupling points 10.

In case of a glass interposer as the workpiece 1, coupling points 10 have a diameter ranging from 20 μm to 450 μm, preferably from 50 μm to 120 μm, with a thickness of the workpiece 1 of less than 1 mm. The center-to-center distance between coupling points 10 ranges from 120 μm to 400 μm. The number of points may range from 10 to 10,000.

During operation of the apparatus, workpiece 1 is subjected to high frequency energy, causing heating of workpiece 1 in general, but especially in the material region between points 10 of coupling material. This leads to a reduction of the dielectric strength of the material, such reduction being most significant in the intermediate region between opposed coupling points 10. An appropriately high voltage from generator 9 then causes dielectric breakdowns 11 across these coupling points 10.

When the method is effected with a plurality of high voltage pulses, the material in the region of breakdowns 11 gets hotter and hotter, the current density increases until the material evaporates and the dielectric breakdown is widened into a hole 12. The eroded perforation material may be removed by purge gas which is introduced and discharged via supply and discharge passages 22, 33.

For the manufacturing of mono- or poly-crystalline solar cells (thickness of about 0.2 mm, edge length of about 150 mm) a silicon semiconductor wafer sheet is used, which has an SiN layer on its front surface. This front surface is printed with a paste at the intended perforation points (from 10 up to more than 10,000 holes; hole diameter from 50 to 200 μm), which paste includes a content of PbO or BiO. The (one-sided) printed semiconductor wafer is heated, e.g. in a furnace, whereby the BiO or PbO reacts with the SiN layer and metallic Pb or Bi is released, which may serve as a local antenna for electro-thermal perforation and is subsequently used as a metallic contact of the Si cell. The effect as a local antenna has been described in conjunction with coupling points 10 in FIG. 1.

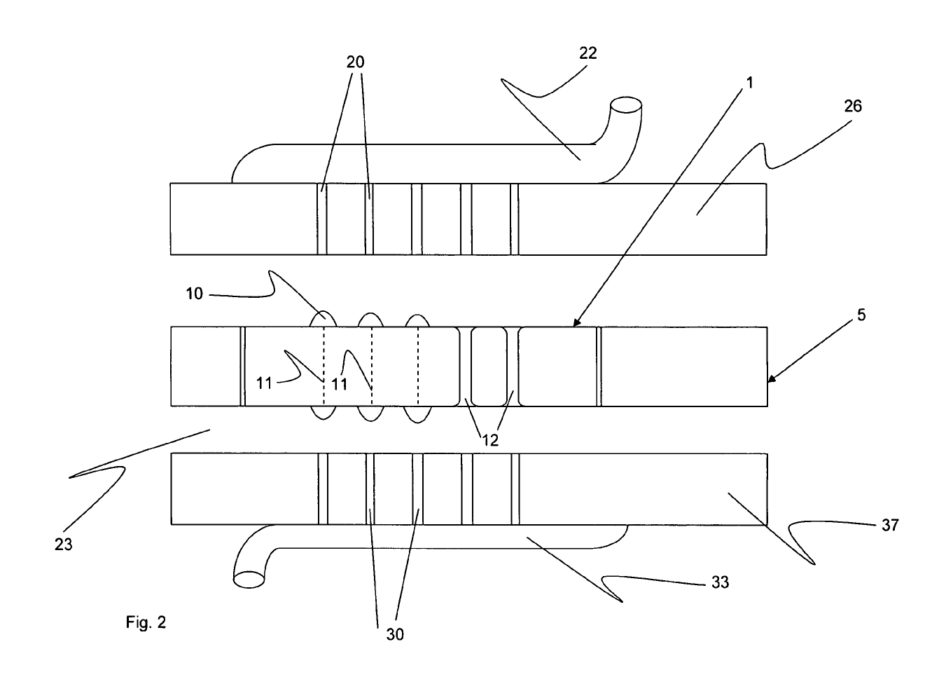

FIG. 2 schematically illustrates an apparatus for chemically widening dielectric breakdowns 11 in workpieces 1. The apparatus is similar to the apparatus of FIG. 1. Processing space 23 is confined by two plates, 26 and 37, which are arranged with a close spacing to workpiece 1 (in contrast to the drawing), and which have mutually aligned nozzles 20, 30, relative to which the perforation points 10 have to be aligned. For this purpose, workpiece holder 5 is provided, which is finely adjustable based on coordinates. A conduit and channel system 22, 33 allows to direct reactive gases and purge gases to the perforation points 10 of workpiece 1.

The operation of the apparatus of FIG. 2 is as follows:

Assuming that workpiece 1 is made of glass having an alkali content of less than 700 ppm, which is suitable for producing an interposer because of its coefficient of expansion. By deep reactive ion etching, the dielectric breakdowns 11 are formed into microholes 12. To this end, etching gases such as CF₄ or SF₆, and passivating gases such as C₄F₈, are alternately directed to the perforation points or the already existing dielectric breakdowns 11, by means of nozzles 20, 30, while the eroded perforation material in form of gaseous silicon halides is removed via processing space 23. An etch mask may be clamped to both sides of workpiece 1 to cover the areas outside the intended perforations. It is possible, to alternately switch the gas streams through nozzles 20 and the gas streams through nozzles 30, in order to provide the holes 12 to be formed with a uniform cylindrical shape in their central portion, while the edges at the inlet and outlet of the channel-shaped holes 12 are ground off. In this manner, holes 12 are produced with a shape as it is required for the final manufacturing of interposers.

The rapid alternation of gas between corrosive and passivating gases and a high gas flow rate result in an increased etch rate which may be up to 20 um/min. Therefore, plasma chemistry is suitable for an industrial production of holes for an industrial mass product such as interposers.

The apparatus of FIGS. 1 and 2 may be combined. Nozzle plates 26 and 37 of FIG. 2 are formed as high-frequency electrodes 2 and 3, with electrode projections 6 and 7 designed in annular form to accommodate the respective outlets of nozzles 20 and 30. Similar to FIG. 1, once the workpiece 1 has been correctly positioned relative to electrodes 2, 3, the electrode plates 2, 3 may be disposed very close to coupling material points 10, in the region of their projections 6, 7.

The operation largely corresponds to the procedure of the method as described above with reference to FIGS. 1 and 2. However, the reactive gases may be supplied while the workpiece 1 is subjected to HF energy, especially as a rapid depletion of silicon may be expected at the stronger heated locations 10, with gaseous silicon halides escaping from the region of the hole being formed, the prospected perforation points adopting a lower melting point (eutectic, flux for glass melts), and removal of material is accelerated, partly because the dielectric breakdown takes place more quickly than with a separate implementation of dielectric breakdown and widening.

1-20. (canceled)

21. A method for producing a multiplicity of holes in thin sheet-like workpieces of dielectric material or semiconductors, the method comprising the steps of:
printing on the work piece a coupling material in form of dots at intended perforation points;
introducing the printed workpiece into a processing space;
activating the coupling material to produce perforation starting points in the workpiece;
generating a high voltage between electrodes to produce dielectric breakdowns at the perforation starting points.

22. The method as claimed in claim 21, further comprising widening the dielectric breakdowns to holes.

23. The method as claimed in claim 21, wherein the printing step comprises printing opposite surfaces of the workpiece with high-frequency coupling material, wherein the processing space is flanked by plate-shaped high-frequency electrodes so that the activating step comprises subjecting the workpiece to high frequency energy that predominantly heats the high frequency coupling material until the workpiece material softens at the perforation starting points, and wherein the generating step comprises forming perforation starting channels in the workpiece at the softened material.

24. The method as claimed in claim 21, wherein the workpiece is made of a material selected from the group consisting of glass, glass-like material, and semiconductor material, and wherein the coupling material comprises glass paste that exhibits high dielectric losses when subjected to high frequency energy.

25. The method as claimed in claim 21, wherein the workpiece is made of a material selected from the group consisting of glass, glass-like material, and semiconductor material, and wherein the coupling material is a paste with conductive components.

26. The method as claimed in claim 25, wherein the paste includes metallic particles.

27. The method as claimed in claim 25, wherein the paste releases metallic particles due to thermal and/or chemical processes.

28. The method as claimed in claim 21, wherein the workpiece is part of a solar cell and one surface thereof is provided with an SiN coating, with which the coupling material reacts chemically upon activation to produce metallic contact points for the solar cell.

29. The method as claimed in claim 28, wherein said coupling material is used as micro-antennas for supplied high frequency energy to cause the dielectric breakdowns.

30. The method as claimed in claim 21, wherein the workpiece is made of glass, the method further comprising supplying halogen containing reactive gases to the processing space to achieve a depletion of Si in a region of dielectric breakdowns.

31. The method as claimed in claim 21, further comprising widening the dielectric breakdowns to holes by deep reactive ion etching.

32. The method as claimed in claim 31, wherein the widening step comprises alternating cycles of etching with CF₄ gas or SF₆ gas and passivation using C₄F₄ gas.

33. The method as claimed in claim 31, further comprising directing reactive gases and/or purge gases onto the holes being formed.

34. A glass interposer comprising a base substrate of glass having an alkali content of less than 700 ppm and holes produced according to the method as claimed in claim 21, the holes having a diameter ranging from 20 μm to 450 μm and having hole walls of fire-polished quality.

35. A solar cell panel comprising a base substrate made of silicon coated with SiN and holes produced according to the method as claimed in claim 1, the holes having diameters ranging from 50 to 200 μm.

36. The solar cell panel as claimed in claim 35, wherein the SiN coating is provided on one surface of the base substrate, and wherein the process of producing holes started with a formation of metallic contact points at the perforations by a reaction with the SiN coating.

37. An apparatus for simultaneously producing a multiplicity of holes in thin sheet-like workpieces of dielectric material or semiconductors having a coupling material in form of dots at intended perforation points, the apparatus comprising:
two mutually parallel electrode plates which delimit a processing space, the plates forming an electrode and a counter electrode;
a workpiece holder for positioning the workpiece in the processing space;
a generator for supplying high-voltage energy to the electrode and counter electrode to cause dielectric breakdowns at the intended perforation points.

38. The apparatus as claimed in claim 37, wherein the generator applies high-frequency voltage to the electrode and counter electrode to heat the coupling material at the intended perforation points.

39. The apparatus as claimed in claim 37, wherein the pair of parallel electrode plates each have nozzle bores aligned towards the intended perforation points, the nozzle bores being connectable to one or more gas supply lines.

40. The apparatus as claimed in claim 37, further comprising flushing channels in fluid communication with the processing space for neutral gas supply and/or gas extraction.
